(19) United States
(12) Patent Application Publication
(10) Pub. No.: US 2008/0305572 A1
(43) Pub. Date: Dec. 11, 2008

(54) METHOD OF FABRICATING IMAGE DEVICE HAVING CAPACITOR AND IMAGE DEVICE FABRICATED THEREBY

(75) Inventors: Young-Sub YOU, Gyeonggi-do (KR); Dae-Han YOO, Seoul (KR); Yong-Woo HYUNG, Gyeonggi-do (KR); Jae-Jong HAN, Seoul (KR); Bi-O KIM, Seoul (KR); Gil-Hwan SON, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/132,542

(22) Filed: Jun. 3, 2008

(30) Foreign Application Priority Data
Jun. 5, 2007 (KR) 10-2007-0055185

(51) Int. Cl. H01L 31/18; H01L 21/02

(52) U.S. Cl. 438/59; 438/393; 257/E21.008; 257/E31.11

(57) ABSTRACT

There are provided a method of fabricating an image device having a capacitor and an image device fabricated thereby. The method comprises preparing a substrate having a pixel region and a peripheral circuit region. A lower electrode containing silicon is formed on the substrate of the peripheral circuit region. A capacitor dielectric layer is formed by sequentially stacking a first dielectric layer and a second dielectric layer on the lower electrode, and the first dielectric layer and the second dielectric layer have a different dielectric constant from each other. In this case, one of the first and second dielectric layers is a dielectric layer grown from a material layer formed thereunder and has a lower dielectric constant than that of the other. An upper electrode is formed on the capacitor dielectric layer.

### CROSS-REFERENCE TO RELATED APPLICATION

This application claims priority under 35 U.S.C. §119 to Korean Patent Application No. 10-2007-0055185, filed on Jun. 5, 2007, the disclosure of which is hereby incorporated herein by reference in its entirety.

### BACKGROUND

1. Technical Field

The present invention relates to an electronic device, and more particularly, to a method of fabricating an image device having a capacitor and an image device fabricated thereby.

2. Description of the Related Art

Generally, an image device, which is a semiconductor module designed to convert an optical image into an electrical signal, is used to store and transmit an image signal to be displayed in a display device. Image devices can be classified as either a charge coupled device (CCD) or a CMOS image sensor (CIS), which is based on a silicon semiconductor. In the electronic products manufactured using the image device, such as, digital cameras, camera phones, and the like, the image quality can be considered as a critical standard in determining the performance of the products. To realize the best image quality in the electronic products, noise generated in the image device needs to be minimized. In order to reduce noise in the image device the reliability of a capacitor in the image device needs to be improved.

An image device has been generally disclosed in U.S. Published Application No. 2006/0164531 A1 entitled “Structure for CMOS Image Sensor.”

### SUMMARY

The present invention is directed to providing a method of fabricating an image device which improves the reliability of a capacitor dielectric layer. Another aspect of the present invention is to provide an image device which has a capacitor with improved reliability.

In an aspect of the present invention, the present invention provides a method of fabricating an image device which improves the reliability of a capacitor dielectric layer. The method comprises: preparing a substrate having a pixel region and a peripheral circuit region; forming a lower electrode containing silicon on the substrate of the peripheral circuit region; and forming a capacitor dielectric layer including a first dielectric layer and a second dielectric layer which are sequentially stacked on the lower electrode and which have a dielectric constant different from each other. In this case, one of the first and second dielectric layers is grown from a material layer formed thereunder and has a lower dielectric constant than that of the other dielectric layer. An upper electrode is formed on the capacitor dielectric layer.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1A through 1E are cross-sectional views of a method of fabricating an image device according to an exemplary embodiment of the present invention;

FIGS. 2A and 2B are cross-sectional views of a method of fabricating an image device according to another exemplary embodiment of the present invention; and

FIG. 3 is a graph of a characteristic of a capacitor of an image device according to the embodiments of the present invention.

### DETAILED DESCRIPTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

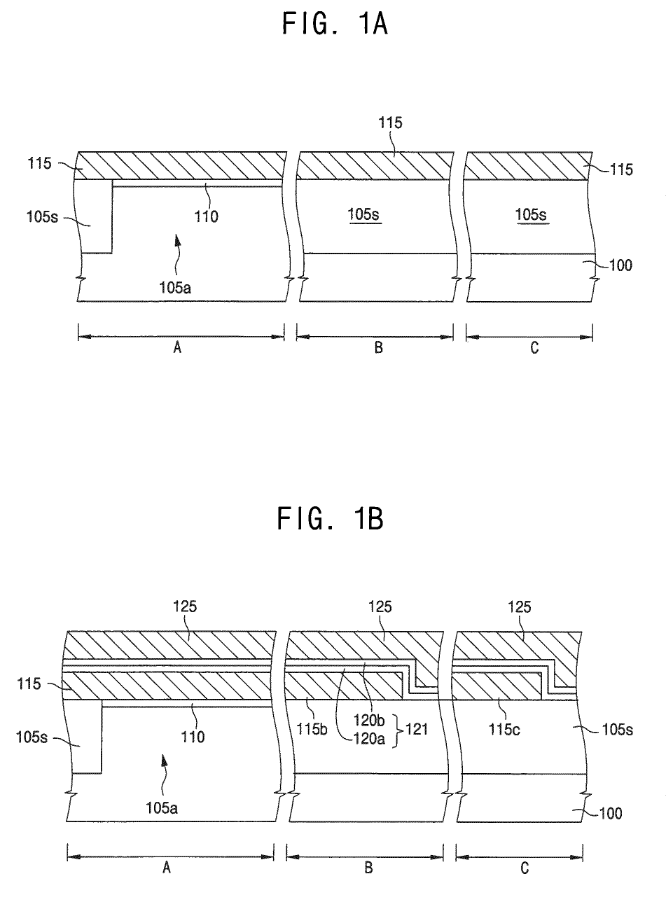

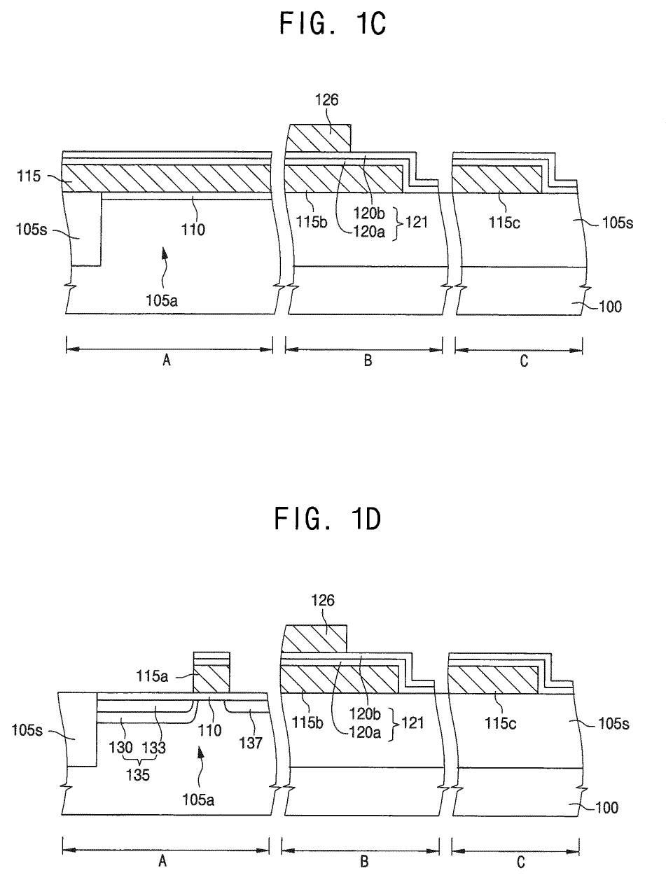

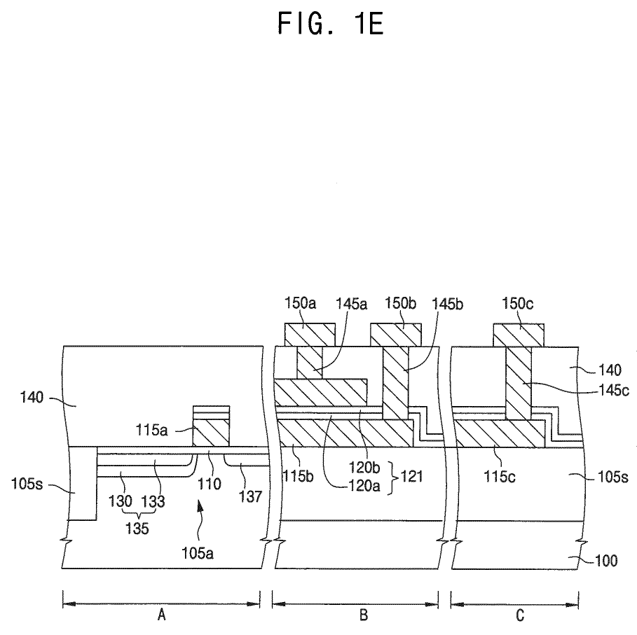

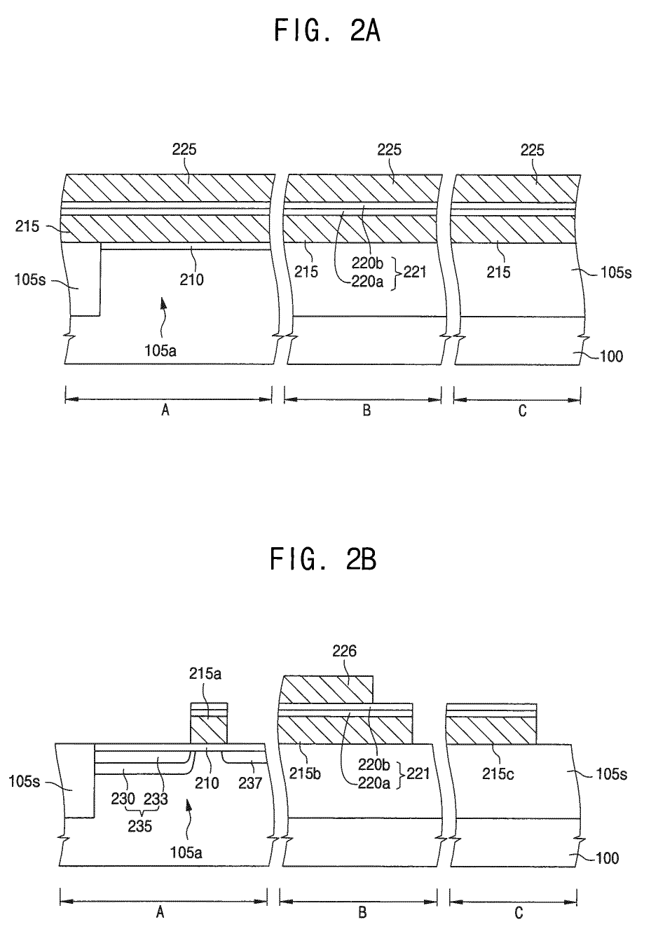

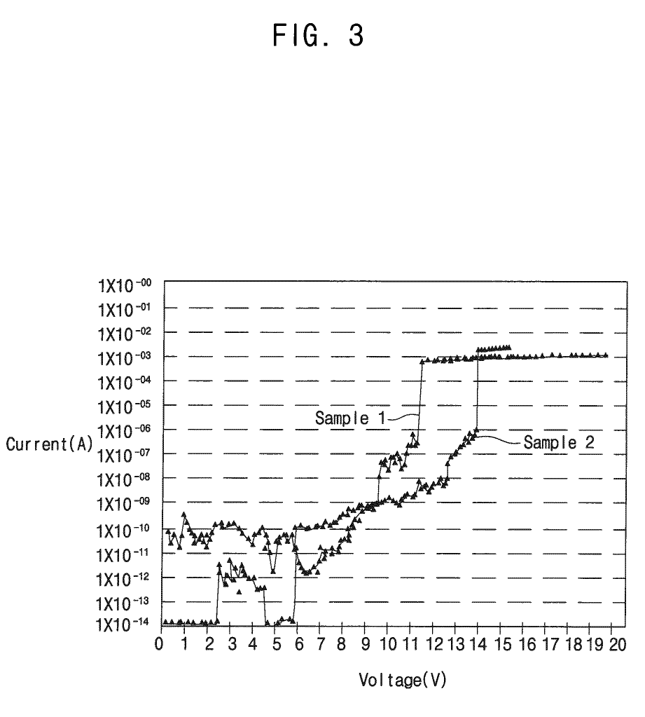

FIGS. 1A through 1E are cross-sectional views of a method of fabricating an image device according to an exemplary embodiment of the present invention; FIGS. 2A and 2B are cross-sectional views of a method of fabricating an image device according to another exemplary embodiment of the present invention; and FIG. 3 is a graph of a characteristic of a capacitor of an image device according to the embodiments of the present invention.

A method of fabricating an image device according to an exemplary embodiment of the present invention will be described with reference to FIGS. 1A through 1E.

Referring to FIG. 1A, a substrate 100 is prepared so as to have a pixel region A, a first peripheral circuit region B and a second peripheral circuit region C. The substrate 100 may be a semiconductor substrate. An isolation region 105s may be formed in a predetermined region of the substrate 100. In the pixel region A, the isolation region 105s may define an active region 105a. The isolation region 105s may be formed in the first and second peripheral circuit regions B and C. The isolation region 105s may be formed of a silicon oxide layer using an isolation process, such as a trench isolation technique.

The isolation region 105s may define peripheral active regions (not shown) within the first and second peripheral circuit regions B and C.

A gate dielectric layer 110 may be formed on the substrate 100 having the isolation region 105s. For example, the gate dielectric layer 110 may be formed of a silicon oxide layer or a high-k dielectric layer having a higher dielectric constant than that of a silicon oxide layer.

A lower conductive layer 115 may be formed on the substrate 100 having the gate dielectric layer 110. The lower conductive layer 115 may contain silicon. For example, the lower conductive layer 115 may be formed of a poly silicon layer.

Referring to FIG. 1B, a lower electrode 115b may be formed by patterning the lower conductive layer 115 on the first peripheral circuit region B. A resistance device 115c may be formed by patterning the lower conductive layer 115 on the second peripheral circuit region C.

The lower electrode 115b and the resistance device 115c may be formed simultaneously. That is, the lower electrode 115b and the resistance device 115c can be formed by patterning the lower conductive layer 115 on the first and second peripheral circuit regions B and C through the same photolithographic and etching processes.

A capacitor dielectric layer 121 including a first dielectric layer 120a and a second dielectric layer 120b which are sequentially stacked on the substrate having the lower electrode 115b may be formed.

In the embodiment of the present invention, the forming of the capacitor dielectric layer 121 may comprise: forming the first dielectric layer 120a as a high-k dielectric layer having a higher dielectric constant than that of a silicon oxide layer; and forming the second dielectric layer 120b as a low-k dielectric layer having a lower dielectric constant than that of the first dielectric layer 120a. In the present invention, the term, “low-k dielectric layer,” is defined as the dielectric layer having a lower dielectric constant than the high-k dielectric layer.

The first dielectric layer 120a may be formed of a high-k dielectric layer containing silicon. For example, the first dielectric layer 120a can be formed of a silicon nitride layer. The first dielectric layer 120a can be formed by chemical vapor deposition (CVD) or atomic layer deposition (ALD). The second dielectric layer 120b may be formed by growing from the first dielectric layer 120a. For example, the second dielectric layer 120b may be formed of a dielectric layer containing silicon and oxygen by using the first dielectric layer 120a as a supply source of the silicon. For example, the second dielectric layer 120b may be formed of a silicon oxide layer or a silicon oxy nitride layer (SiON) grown from the first dielectric layer 120a.

The second dielectric layer 120b may be formed by growing from the first dielectric layer 120a, using thermally-dissociated oxygen radicals. For example, the second dielectric layer 120b can be formed in a processing chamber at a temperature sufficient to change an oxygen gas to oxygen radicals, for example, a high temperature ambient being above 900° C. That is, the second dielectric layer 120b can be formed by using the oxygen radicals thermally-dissociated from the oxygen gas. The second dielectric layer 120b may be formed by performing an oxidation process in single-type semiconductor equipment, in which the oxidation process is performed on a single wafer, or in batch-type semiconductor equipment, in which the oxidation process is performed on a plurality of wafers.

The second dielectric layer 120b may be formed in a processing ambient further including at least one of a hydrogen gas and an inactive gas in addition to the thermally-dissociated oxygen radicals.

The second dielectric layer 120b may be formed by growing from the first dielectric layer 120a in a processing ambient including an NO gas or N₂O gas in addition to an oxygen gas. Accordingly, the second dielectric layer 120b may be formed of a silicon oxy nitride (SiON) layer.

The second dielectric layer 120b may be formed by growing from the first dielectric layer 120a in a processing ambient including an HCl (hydrochloric acid) gas and an oxygen gas. The HCl gas removes contaminated materials on the surface of the lower electrode 115b.

The second dielectric layer 120b may be formed by growing from the first dielectric layer 120a in a processing ambient of atmospheric pressure or lower pressure than the atmospheric pressure. The forming of the second dielectric layer 120b in the processing ambient of the lower pressure is to control a growth rate of the second dielectric layer 120b. That is, a growth thickness of the second dielectric layer 120b can be controlled by growing the second dielectric layer 120b from the first dielectric layer 120a in the lower pressure processing ambient.

In another embodiment, the forming of the capacitor dielectric layer 121 may comprise: forming the first dielectric layer 120a containing silicon and oxygen; and forming the second dielectric layer 120b which has a higher dielectric constant than that of the first dielectric layer 120a. That is, the first dielectric layer 120a may be formed of a low-k dielectric layer having a relatively lower dielectric constant than that of the second dielectric layer 120b. The second dielectric layer 120b may be formed of a silicon nitride layer.

The first dielectric layer 120a may be formed of a dielectric layer containing silicon and oxygen by growing from the lower electrode 115b. The lower electrode 115b may be used as the supply source of the silicon for the first dielectric layer 120a. For example, the first dielectric layer 120a may be formed of a silicon oxy nitride layer or a silicon oxide layer.

The first dielectric layer 120a may be formed by growing from the lower electrode 115b by using the thermally-dissociated oxygen radicals. For example, the first dielectric layer 120a may be formed in a processing chamber with a high temperature ambient sufficient to change the oxygen gas into oxygen radicals. That is, the first dielectric layer 120a may be formed by using the oxygen radicals thermally dissociated from the oxygen gas. The first dielectric layer 120a may be formed in a processing ambient further including at least one of a hydrogen gas and an inactive gas in addition to the thermally-dissociated oxygen radicals.

The first dielectric layer 120a may be formed by growing from the lower electrode 115b in a processing ambient including an NO gas or N₂O gas in addition to an oxygen gas. Accordingly, the first dielectric layer 120a may be formed of a silicon oxy nitride (SiON) layer.

The first dielectric layer 120a may be formed by growing from the lower electrode 115b in a processing ambient including an HCl gas and an oxygen gas. The HCl gas removes contaminated materials on the surface of the lower electrode 115b.

The first dielectric layer 120a may be formed by growing from the lower electrode 115b in a processing ambient of atmospheric pressure or lower pressure than the atmospheric pressure. The forming of the first dielectric layer 120a in the processing ambient of the lower pressure is to control a growth rate of the first dielectric layer 120a. That is, a growth thickness of the first dielectric layer 120a can be controlled by growing the first dielectric layer 120a from the lower electrode 115b in the processing ambient of the lower pressure.

An upper conductive layer 125 may be formed on the capacitor dielectric layer 121. The upper conductive layer 125 may be formed of a poly silicon layer.

Referring to FIG. 1C, an upper electrode 126 may be formed on the first peripheral circuit region B by patterning the upper conductive layer 125 on the first peripheral circuit region B. The upper electrode 126, the capacitor dielectric layer 121 and the lower electrode 115b may form a capacitor. Such a capacitor has improved reliability because one of the first dielectric layer 120a and the second dielectric layer 120b forming the capacitor dielectric layer 121 is formed by growing from a lower layer in a high temperature ambient.

The upper conductive layer 125 on the pixel region A and the second peripheral circuit region C may be etched so as to be removed while the upper conductive layer 125 on the first peripheral circuit region B is patterned.

Referring to FIG. 1D, a gate electrode 11 Sa may be formed by patterning the lower conductive layer on the pixel region A. The capacitor dielectric layer of the pixel region A can remain on the gate electrode 115a.

According to some embodiments of the invention, the gate electrode 115a, the lower electrode 115b and the resistance device 115c may be formed by using a material formed through the same process. Accordingly, the productivity of the image device is improved.

A first impurity region 130 of a first conductivity type may be formed by selectively implanting impurity ions of a first conductivity type into the active region 105a proximate to one of the sidewalls of the gate electrode 115a. The first impurity region 130 may have a different conductivity type from that of the active region 105a. For example, the active region 105a of the substrate 100 may be p-type and the first impurity region 130 may be n-type. A second impurity region 133 of a different conductivity type than that of the first impurity region 130 may be formed by selectively implanting impurity ions of a second conductivity type to the surface of the first impurity region 130. More specifically, the first impurity region 130 may be formed by forming a photo-resist pattern having an opening to expose the active region 105a proximate to one of the sidewalls of the gate electrode 115a and by implanting the impurity ions of the first conductivity type to the exposed active region 105a by using the photo-resist pattern as an ion implantation mask. Subsequently, the second impurity region 133 may be formed by implanting the impurity ions of the second conductivity type different from the first conductivity type to the surface of the first impurity region 130, and then the photo-resist pattern is removed. The first impurity region 130 may be formed to overlap the gate electrode 115a. Further, the second impurity region 133 may be formed to be surrounded by the first impurity region 130. The first impurity region 130 and the second impurity region 133 may form a photo diode 135 of the image device.

A third impurity region 137 of the same conductivity type as that of the first impurity region 130 may be formed on the active region 105a positioned to be opposite to the first impurity region 130, so that the gate electrode 115a is interposed between the third impurity region 137 and the first impurity region 130. Accordingly, the first impurity region 130 and the third impurity region 137 face each other at either side of the gate electrode 115a.

Referring to FIG. 1E, an interlayer insulating layer 140 may be formed on the substrate having the photo diode 135 and the third impurity region 137. The interlayer insulating layer 140 may be formed of a silicon oxide layer. A first contact plug 145a, a second contact plug 145b and a third contact plug 145c may be formed so as to be spaced apart from one another, through the interlayer insulating layer 140. The first contact plug 145a may be formed to electrically contact with the upper electrode 126, the second contact plug 145b may be formed to electrically contact with the lower electrode 115b, and the third contact plug 145c may be formed to electrically contact with the resistance device 115c. While the third contact plug 145c is formed, a fourth contact plug (not shown) may be formed to be in contact with the resistance device 115c and to be spaced apart from the third contact plug 145c. A first metal interconnection 150a, a second metal interconnection 150b and a third metal interconnection 150c may be formed on the interlayer insulating layer 140, to respectively cover the first contact plug 145a, the second contact plug 145b and the third contact plug 145c.

A method of fabricating an image device according to another embodiment of the present invention will be described with reference to FIGS. 2A and 2B.

Referring to FIG. 2A, the substrate 100 having the pixel region A, the first peripheral circuit region B and the second peripheral circuit region C, as described with reference to FIG. 1A, is prepared. An isolation region 105s may be formed in a predetermined region of the substrate 100, to define the active region 105a on the pixel region A, as described with reference to FIG. 1A.

A gate dielectric layer 210 may be formed on the substrate 100 having the isolation region 105s. For example, the gate dielectric layer 210 may be formed of a silicon oxide layer or a high-k dielectric layer having a higher dielectric constant than that of the silicon oxide layer. A lower conductive layer 215 may be formed on the substrate 100 having the gate dielectric layer 210. The lower conductive layer 215 may contain silicon. For example, the lower conductive layer 215 may be formed of a poly silicon layer.

A capacitor dielectric layer 221 may be formed on the lower conductive layer 215. The capacitor dielectric layer 221 includes a first dielectric layer 220a and a second dielectric layer 220b which are sequentially stacked by using the substantially same method as the method of forming the capacitor dielectric layer 121 as described with reference to FIG. 1B. That is, the forming of the capacitor dielectric layer 221 may comprise: forming the first dielectric layer 220a of a high-k dielectric layer having a higher dielectric constant than that of the silicon oxide layer; and forming the second dielectric layer 220b being grown from the first dielectric layer 220a. Alternatively, the forming of the capacitor dielectric layer 221 may comprise: forming the first dielectric layer 220a being grown from the lower conductive layer 215; and forming the second dielectric layer 220b of a higher dielectric constant than that of the first dielectric layer 220a.

Subsequently, an upper conductive layer 225 may be formed on the capacitor dielectric layer 221. The upper conductive layer 225 may be formed of a poly silicon layer.

Referring to FIG. 2B, an upper electrode 226 may be formed on the first peripheral circuit region B by patterning the upper conductive layer (225 of FIG. 2A). While the upper conductive layer (225 of FIG. 2A) is patterned, the upper connective layer (225 of FIG. 2A) on the second peripheral circuit region C can be removed. While the upper conductive layer (225 of FIG. 2A) is patterned, the upper conductive layer (225 of FIG. 2A) on the pixel region A can be removed.

In the first peripheral circuit region B, a lower electrode 215b having a broader area than the upper electrode 226 may be formed by patterning the lower conductive layer (215 of FIG. 2A). While the lower conductive layer (215 of FIG. 2A) is patterned in the first peripheral circuit region B, the capacitor dielectric layer 221 may remain under the upper electrode 226. In the first peripheral circuit region B, the upper electrode 226, the capacitor dielectric layer 221 and the lower electrode 215b may form a capacitor.

In the pixel region A, a gate electrode 215a may be formed by patterning the lower conductive layer (215 of FIG. 2A). The gate electrode 215a and the lower electrode 215b may be formed simultaneously.

In the second peripheral circuit region C, a resistance device 215c may be formed by patterning the lower conductive layer (215 of FIG. 2A). The resistance device 215c and the lower electrode 215b may be formed simultaneously.

A first impurity region 230 of a first conductivity type may be formed by selectively implanting impurity ions of the first conductivity type into the active region 105a proximate to one of the sidewalls of the gate electrode 215a. The first impurity region 230 may have a different conductivity type than the active region 105a. For example, the active region 105a of the substrate 100 may be p-type and the first impurity region 230 may be n-type. A second impurity region 233 of a different conductivity type than the first impurity region 230 may be formed by selectively implanting impurity ions of a second conductivity type to the surface of the first impurity region 230. More specifically, the first impurity region 230 may be formed by forming a photo-resist pattern having an opening to expose the active region 105a proximate to one of the sidewalls of the gate electrode 215a and by implanting the impurity ions of the first conductivity type to the exposed active region 105a by using the photo-resist pattern as an ion implantation mask. Subsequently, the second impurity region 233 may be formed by implanting the impurity ions of the second conductivity type different from the first conductivity type to the surface of the first impurity region 230, and then the photo-resist pattern may be removed. The first impurity region 230 may be formed so as to overlap with the gate electrode 215a. Further, the second impurity region 233 may be formed so as to be surrounded by the first impurity region 230. The first impurity region 230 and the second impurity region 233 may form a photo diode 235 of the image device.

A third impurity region 237 of the same conductivity type as that of the first impurity region 230 may be formed on the active region 105a positioned to be opposite to the first impurity region 230, so that the gate electrode 215a is interposed between the third impurity region 237 and the first impurity region 230. Accordingly, the first impurity region 230 and the third impurity region 237 face each other at either side of the gate electrode 215a.

A structure of the image device according to the embodiments of the present invention will be described below:

Referring to FIG. 1E, a substrate 100 having a pixel region A, a first peripheral circuit region B and a second peripheral circuit region C may be provided. The substrate 100 may be a semiconductor substrate. An isolation region 105s may be provided in a predetermined region of the substrate 100. In the pixel region A, the isolation region 105s may define an active region 105a. The isolation region 105s may define peripheral active regions (not shown) within the first and second peripheral circuit regions B and C.

A gate dielectric layer 110 and a gate electrode 115a being sequentially stacked may be provided on the active region 105a of the pixel region A. The gate dielectric layer 110 may be a silicon oxide layer or a high-k dielectric layer having a higher dielectric constant than that of the silicon oxide layer. The gate electrode 115a may be a conductive layer containing silicon. For example, the gate electrode 115a may be a poly silicon layer.

A first impurity region 130 of a first conductivity type may be provided in the active region 105a proximate to one of the sidewalls of the gate electrode 115a. The first impurity region 130 may have a different conductivity type from that of the active region 105a. For example, the active region 105a of the substrate 100 may be p-type and the first impurity region 130 may be n-type. The first impurity region 130 may overlap with the gate electrode 115a. A second impurity region 133 may be provided in the first impurity region 130. For example, the second impurity region 133 may be provided to the surface of the first impurity region 130 so as to be surrounded by the first impurity region 130. The first impurity region 130 and the second impurity region 133 may form a photo diode 135 of the image device. A third impurity region 137 of the same conductivity type as that of the first impurity region 130 may be provided in the active region 105a positioned to be opposite to the first impurity region 130, so that the gate electrode 115a is interposed between the third impurity region 137 and the first impurity region 130. That is, the first impurity region 130 and the third impurity region 137 face each other at either side of the gate electrode 115a.

A lower electrode 115b, a capacitor dielectric layer 121 and an upper electrode 126 which are sequentially stacked on the substrate 100 of the first peripheral circuit region B, may be provided. The capacitor dielectric layer 121 may include a first dielectric layer 120a and a second dielectric layer 120b being sequentially stacked. The lower electrode 115b may be a conductive layer containing silicon. For example, the lower electrode 115b may be a poly silicon layer. The upper electrode 126 may also be a poly silicon layer.

In an embodiment of the present invention, the first dielectric layer 120a may be a high-k dielectric layer having a higher dielectric constant than that of a silicon oxide layer and the second dielectric layer 120b may be a dielectric layer having a lower dielectric constant than that of the first dielectric layer 120a. The first dielectric layer 120a may be a dielectric layer containing silicon. For example, the first dielectric layer 120a may be formed of a silicon nitride layer. The second dielectric layer 120b may be a dielectric layer grown from the first dielectric layer 120a. For example, the second dielectric layer 120b may be formed of a silicon oxide layer or a silicon oxy nitride layer.

In another embodiment, the first dielectric layer 120a may be a dielectric layer grown from the lower electrode 115b. The second dielectric layer 120b may be a dielectric layer having a higher dielectric constant than that of the first dielectric layer 120a. For example, the first dielectric layer 120a may be formed of a silicon oxide layer or a silicon oxy nitride layer and the second dielectric layer 120b may be formed of a silicon nitride layer.

A resistance device 115c may be provided on the substrate 100 of the second peripheral circuit region C. The resistance device 115c may be a poly silicon layer. According to some embodiments of the present invention, the gate electrode 115a, the lower electrode 115b and the resistance device 115c may be formed by using a material layer formed through the same process. Accordingly, the gate electrode 115a, the lower electrode 115b and the resistance device 115c may be positioned on the substantially same level.

A first metal interconnection 150a electrically connected to the upper electrode 126, a second metal interconnection 150b electrically connected to the lower electrode 115b, and a third metal interconnection 150c electrically connected to the resistance device 115c will be provided. Further, a fourth metal interconnection (not shown) may be provided so as to be electrically connected to the resistance device 115c and to be spaced apart from the third metal interconnection 150c. A first contact plug 145a interposed between the upper electrode 126 and the first metal interconnection 150a, a second contact plug 145b interposed between the lower electrode 115b and the second metal interconnection 150b, and a third contact plug 145c interposed between the resistance device 115c and the third metal interconnection 150c may be provided.

### RELIABILITY EXAMPLE

Characteristics of a breakdown voltage will be described by comparing Sample 1 fabricated according to the conventional art and Sample 2 fabricated according to the exemplary embodiment of the present invention.

FIG. 3 is a graph of the characteristics of the breakdown voltage of a capacitor of an image device. In FIG. 3, Samples 1 and 2 are formed to have a capacitor structure similar to that illustrated in FIG. 1E. In Samples 1 and 2, upper/lower electrodes are formed of a poly silicon layer. In Sample 1, a capacitor dielectric layer is formed of a silicon nitride layer on the lower electrode and a medium temperature oxide (generally, MTO) layer is deposited on the silicon nitride layer. In Sample 2, a capacitor dielectric layer is formed of a silicon nitride layer on the lower electrode like Sample 1 and an oxide layer is grown from the silicon nitride layer on the silicon nitride layer unlike Sample 1. As described in the embodiment of the present invention, the oxide layer is grown from the silicon nitride layer by using thermally-dissociated oxygen radicals in a processing chamber with a temperature of 950° C. and a pressure of 7.5 Torr. As a result, the capacitor dielectric layer of Sample 1 is formed of the silicon nitride layer being 60 Å in thickness and the silicon oxide layer being 30 Å in thickness, and the capacitor dielectric layer of Sample 2 is formed of the silicon nitride layer being 60 Å in thickness and the silicon oxide layer being 25 Å in thickness.

In FIG. 3, the breakdown voltage of Sample 1 is 11.5V and the breakdown voltage of Sample 2 is 13.9V. The thickness of the oxide layer of Sample 1 is 30 Å and the thickness of the oxide layer of Sample 2 is 25 Å. Accordingly, it can be noticed that the breakdown voltage of Sample 2 is higher than that of Sample 1 even though the thickness of the capacitor dielectric layer of Sample 2 is thinner than that of Sample 1. Consequently, with respect to the reliability of a capacitor, the capacitor of Sample 2 having the oxide layer grown from the lower material layer has the characteristics of a better breakdown voltage than the capacitor of Sample 1 having the oxide layer deposited on the lower material layer.

In an aspect of the present invention, the present invention provides a method of fabricating an image device which improves the reliability of a capacitor dielectric layer. The method comprises: preparing a substrate having a pixel region and a peripheral circuit region; forming a lower electrode containing silicon on the substrate of the peripheral circuit region; and forming a capacitor dielectric layer including a first dielectric layer and a second dielectric layer which are sequentially stacked on the lower electrode and which have a dielectric constant different from each other. In this case, one of the first and second dielectric layers is grown from a material layer formed thereunder and has a lower dielectric constant than that of the other dielectric layer. An upper electrode is formed on the capacitor dielectric layer.

In exemplary embodiments of the present invention, the forming of the lower electrode may comprise: forming a lower conductive layer containing silicon on the surface of the substrate having the pixel region and the peripheral circuit region; and patterning the lower conductive layer on the peripheral circuit region.

The method may further comprise: before forming the lower conductive layer, forming a gate dielectric layer on the substrate having the pixel region and the peripheral circuit region; after forming the lower conductive layer, patterning the lower conductive layer of the pixel region and forming a gate electrode on the gate dielectric layer of the pixel region.

The method may further comprise: forming a photodiode on the substrate of the pixel region proximate to a sidewall of the gate electrode.

The method may further comprise: after forming the lower conductive layer, forming a resistance device by patterning the lower conductive layer on the peripheral circuit region.

Further, when the second dielectric layer among the first and second dielectric layers has a lower dielectric constant, the forming of the capacitor dielectric layer may comprise: forming the first dielectric layer to contain silicon; and growing the second dielectric layer as an oxide layer containing silicon from the first dielectric layer by using the first dielectric layer as a source of the silicon.

Further, when the dielectric constant of the first dielectric layer among the first and second dielectric layers is lower than that of the second dielectric layer, the forming of the capacitor dielectric layer may comprise: growing the first dielectric layer as an oxide layer containing silicon from the lower electrode using the lower electrode as the source of the silicon; and forming the second dielectric layer on the first dielectric layer.

Further, the dielectric layer having a higher dielectric constant, among the first and second dielectric layers, may be formed to contain a silicon nitride layer.

Further, the growing of the dielectric layer having the lower dielectric constant, among the first and second dielectric layers, may comprise: thermally-dissociating oxygen radicals from an oxygen gas.

The growing of the dielectric layer having the lower dielectric constant, among the first and second dielectric layer, may be performed in a processing ambient further including at least one of a hydrogen gas and an inactive gas in addition to the oxygen radicals.

Further, the growing of the dielectric layer having the lower dielectric constant, among the first and second dielectric layers, may comprise: using a processing ambient of atmospheric pressure or less.

Further, the growing of the dielectric layer having the lower dielectric constant, among the first and second dielectric layers, may comprise: using a processing ambient including an HCl gas and an oxygen gas.

Further, the growing of the dielectric layer having the lower dielectric constant, among the first and second dielectric layers, may comprise: using a processing ambient including a mixed gas of an NO gas and an oxygen gas or an N₂O gas and the oxygen gas.

In another aspect of the present invention, the present invention provides a method of fabricating an image device having a capacitor. The method comprises: preparing a substrate having a pixel region and a peripheral circuit region; forming a lower conductive layer containing silicon on the substrate having the pixel region and the peripheral circuit region; and forming a capacitor dielectric layer including a first dielectric layer and a second dielectric layer sequentially stacked on the lower conductive layer and which have a dielectric constant different from each other. A selected one of the first and second dielectric layers is grown from a material layer formed thereunder and has a dielectric constant lower than that of the other dielectric layer. An upper electrode is formed on the capacitor dielectric layer. A lower electrode is formed by patterning the lower conductive layer on the peripheral circuit region. A gate electrode is formed by patterning the lower conductive layer on the pixel region.

In exemplary embodiments of the present invention, the gate electrode and the lower electrode may be formed substantially simultaneously.

Further, the method may further comprise: forming a resistance device by patterning the lower conductive layer on the peripheral circuit region, in which the resistance device and the gate electrode may be formed substantially simultaneously.

Further, when the second dielectric layer among the first and second dielectric layers has a lower dielectric constant, the forming of the capacitor dielectric layer may comprise: forming the first dielectric layer including silicon; and growing the second dielectric layer as an oxide layer containing silicon from the first dielectric layer using the first dielectric layer as a source of the silicon.

Further, when the dielectric constant of the first dielectric layer among the first and second dielectric layers is lower than that of the second dielectric layer, the forming of the capacitor dielectric layer may comprise: growing the first dielectric layer as an oxide layer containing silicon from the lower conductive layer using the lower conductive layer as the source of the silicon; and forming the second dielectric layer on the first dielectric layer.

In another aspect of the present invention, the present invention provides a method of fabricating a capacitor. The method comprises: forming a lower electrode on a substrate; forming a capacitor dielectric layer including a first dielectric layer and a second dielectric layer sequentially stacked on the lower electrode and which have a dielectric constant different from each other, wherein a selected one of the first and second dielectric layers is grown from a material layer formed thereunder and has a lower dielectric constant than that of the other dielectric layer; and forming an upper electrode on the capacitor dielectric layer.

In exemplary embodiments of the present invention, when the second dielectric layer among the first and second dielectric layers has a lower dielectric constant, the forming of the capacitor dielectric layer may comprise: forming the first dielectric layer including silicon; and growing the second dielectric layer as an oxide layer containing silicon from the first dielectric layer using the first dielectric layer as a source of the silicon.

Further, when the dielectric constant of the first dielectric layer among the first and second dielectric layers is lower than that of the second dielectric layer, the forming of the capacitor dielectric layer may comprise: growing the first dielectric layer as an oxide layer containing silicon from the lower electrode using the lower electrode as a source of the silicon; and forming the second dielectric layer on the first dielectric layer.

In another aspect of the present invention, the present invention provides an image device having a capacitor. The image device comprises: a substrate having a pixel region and a peripheral circuit region; a lower electrode containing silicon formed on the peripheral circuit region; a capacitor dielectric layer formed on the lower electrode and including a first dielectric layer and a second dielectric layer which are sequentially stacked and have a dielectric constant being different from each other, in which one of the first and second dielectric layers is grown from a material layer formed thereunder and has the dielectric constant being lower than that of the other dielectric layer. An upper electrode is formed on the capacitor dielectric layer. A gate dielectric layer and a gate electrode which are sequentially staked are formed on the pixel region.

In exemplary embodiments of the present invention, the image device may further comprise: a photodiode provided on the substrate of the pixel region proximate to a sidewall of the gate electrode.

Further, when the dielectric layer formed at a lower position, among at least the two dielectric layers, has a lower dielectric constant, the dielectric layer formed at the lower position among the dielectric layers may be an oxide layer formed by silicon supplied from the lower electrode.

Also, when the dielectric layer formed at a higher position, among at least the two dielectric layers, has the lower dielectric constant, the dielectric layer formed at the lower position among the dielectric layers may contain silicon and the dielectric layer formed at the higher position may be an oxide layer formed by the silicon supplied from the dielectric layer formed at the lower position.

As described above, in accordance with the embodiments of the present invention, there is provided the image device having the capacitor dielectric layer of the improved reliability. Since the image device uses the oxide layer grown from the lower material layer as the capacitor dielectric layer, the characteristics of the breakdown voltage of the capacitor is improved. Accordingly, the image device provides the capacitor with the improved reliability. Furthermore, the noise of the image device, for example, random noise, is minimized.

What is claimed is:

1. A method of fabricating an image device, comprising:
preparing a substrate having a pixel region and a peripheral circuit region;
forming a lower electrode including silicon on the substrate in the peripheral circuit region;
forming a capacitor dielectric layer including a first dielectric layer and a second dielectric layer sequentially stacked on the lower electrode and having a different dielectric constant from each other, in which one of the first and second dielectric layers is grown from a material layer formed thereunder and has a lower dielectric constant than that of the other; and
forming an upper electrode on the capacitor dielectric layer.

2. The method according to claim 1, wherein the forming of the lower electrode comprises:
forming a lower conductive layer containing silicon on the surface of the substrate having the pixel region and the peripheral circuit region; and
patterning the lower conductive layer in the peripheral circuit region.

3. The method according to claim 2, further comprising:
before the forming of the lower conductive layer, forming a gate dielectric layer on the substrate having the pixel region and the peripheral circuit region; and
after the forming of the lower conductive layer, forming a gate electrode on the gate dielectric layer in the pixel region by patterning the lower conductive layer in the pixel region.

4. The method according to claim 3, further comprising:
forming a photo diode on the substrate in the pixel region proximate to a sidewall of the gate electrode.

5. The method according to claim 2, further comprising:
after the forming of the lower conductive layer, forming a resistance device by patterning the lower conductive layer in the peripheral circuit region.

6. The method according to claim 1, wherein, when the second dielectric layer, among the first and second dielectric layers, is grown from the material layer formed thereunder, the forming of the capacitor dielectric layer comprises:
forming the first dielectric layer as a dielectric layer containing silicon; and
growing the second dielectric layer as an oxide layer containing silicon from the first dielectric layer using the first dielectric layer as a source of the silicon.

7. The method according to claim 1, wherein, when the first dielectric layer, among the first and second dielectric layers, is grown from the material layer formed thereunder, the forming of the capacitor dielectric layer comprises:
growing the first dielectric layer as an oxide layer containing silicon from the lower electrode using the lower electrode as a source of the silicon; and
forming the second dielectric layer on the first dielectric layer.

8. The method according to claim 1, wherein the dielectric layer having a higher dielectric constant, among the first and second dielectric layers, is formed so as to include a silicon nitride layer.

9. The method according to claim 1, wherein the growing of the dielectric layer having a lower dielectric constant, among the first and second dielectric layers, comprises: thermally dissociating oxygen radicals from an oxygen gas.

10. The method according to claim 9, wherein the growing of the dielectric layer having a lower dielectric constant, among the first and second dielectric layers, is performed in a processing ambient further including at least one of a hydrogen gas and an inactive gas in addition to the oxygen radicals.

11. The method according to claim 1, wherein the growing of the dielectric layer having a lower dielectric constant, among the first and second dielectric layers, comprises: using a processing ambient of atmospheric pressure or less.

12. The method according to claim 1, wherein the growing of the dielectric layer having a lower dielectric constant, among the first and second dielectric layers, comprises: using a processing ambient including an HCl gas and an oxygen gas.

13. The method according to claim 1, wherein the growing of the dielectric layer having a lower dielectric constant, among the first and second dielectric layers, comprises: using a processing ambient including a mixed gas of an NO gas and an oxygen gas or a mixed gas of an N₂O gas and an oxygen gas.

14. A method of fabricating an image device, comprising:
preparing a substrate having a pixel region and a peripheral circuit region;
forming a lower conductive layer including silicon on the substrate having the pixel region and the peripheral circuit region;
forming a capacitor dielectric layer including a first dielectric layer and a second dielectric layer sequentially stacked on the lower conductive layer and having a different dielectric constant from each other, wherein a selected one of the first and second dielectric layers is grown from a material layer formed thereunder and has a lower dielectric constant than that of the other of the first and second dielectric layers;
forming an upper electrode on the capacitor dielectric layer;
forming a lower electrode by patterning the lower conductive layer on the peripheral circuit region; and
forming a gate electrode by patterning the lower conductive layer on the pixel region.

15. The method according to claim 14, wherein the gate electrode and the lower electrode are formed substantially simultaneously.

16. The method according to claim 14, further comprising:
forming a resistance device by patterning the lower conductive layer on the peripheral circuit region, in which the resistance device and the gate electrode are formed substantially simultaneously.

17. The method according to claim 14, wherein the second dielectric layer is the selected one of the first and second dielectric layers, and wherein the forming of the capacitor dielectric layer comprises:
forming the first dielectric layer as a dielectric layer containing silicon; and
growing the second dielectric layer as an oxide layer containing silicon from the first dielectric layer using the first dielectric layer as a source of the silicon.

18. The method according to claim 14, wherein the first dielectric layer is the selected one of the first and second dielectric layers, and wherein the forming of the capacitor dielectric layer comprises:
growing the first dielectric layer as an oxide layer containing silicon from the lower conductive layer using the lower conductive layer as a source of the silicon; and
forming the second dielectric layer on the first dielectric layer.

19. A method of fabricating a capacitor, comprising:
forming a lower electrode on a substrate;
forming a capacitor dielectric layer including a first dielectric layer and a second dielectric layer sequentially stacked on the lower electrode and having a different dielectric constant from each other, wherein a selected one of the first and second dielectric layers is a dielectric layer grown from a material layer formed thereunder and has a lower dielectric constant than that of the other of the first and second dielectric layers; and
forming an upper electrode on the capacitor dielectric layer.

20. The method according to claim 19, wherein the second dielectric layer is the selected one of the first and second dielectric layers, and wherein the forming of the capacitor dielectric layer comprises:
forming the first dielectric layer as a dielectric layer containing silicon; and
growing the second dielectric layer as an oxide layer containing silicon from the first dielectric layer using the first dielectric layer as a source of the silicon.

21. The method according to claim 19, wherein the first dielectric layer is the selected one of the first and second dielectric layers, and wherein the forming of the capacitor dielectric layer comprises:
growing the first dielectric layer as an oxide layer containing silicon from the lower electrode using the lower electrode as a source of the silicon; and
forming the second dielectric layer on the first dielectric layer.
